(19) United States
(12) Patent Application Publication
(10) Pub. No.: US 2026/0068234 A1
(43) Pub. Date: Mar. 5, 2026

(54) CAPACITIVE READ-OUT MODE FOR FERROELECTRIC FIELD EFFECT TRANSISTOR

(71) Applicant: Georgia Tech Research Corporation, Atlanta, GA (US)

(72) Inventor: Shimeng Yu, Atlanta, GA (US)

(21) Appl. No.: 19/309,301

(22) Filed: Aug. 25, 2025

Related U.S. Application Data
(60) Provisional application No. 63/689,226, filed on Aug. 30, 2024.

(51) Int. Cl. H10D 30/69; G06N 3/065; G11C 11/22; H10B 51/30; H10D 62/80; H10D 62/83; H10D 64/68

(52) U.S. Cl. CPC H10D 30/701; G06N 3/065; G11C 11/2273; G11C 11/2275; H10B 51/30; H10D 62/83; H10D 62/875; H10D 64/689

(57) ABSTRACT

The present disclosure provides a method for operating a ferroelectric field effect transistor (FeFET) as a capacitive memory device. The method comprises connecting a source terminal and a drain terminal of the FeFET together, applying a small-signal voltage to a gate terminal of the FeFET at zero direct-current gate voltage, and measuring capacitance between the gate terminal and the connected source and drain terminals to determine a capacitance state of the FeFET. The capacitance state corresponds to either a high capacitance state or a low capacitance state based on polarization of a ferroelectric gate stack of the FeFET. The disclosure also provides a FeFET device configured for capacitive memory operation comprising a semiconductor channel, a ferroelectric gate stack disposed over the semiconductor channel, a gate terminal connected to the ferroelectric gate stack, a source terminal and a drain terminal connected to the semiconductor channel, and a body terminal. The FeFET device is configured to operate in a capacitive read-out mode where capacitance is measured between the gate terminal and connected source and drain terminals at zero direct-current gate voltage to determine a memory state.

### CROSS-REFERENCE TO RELATED APPLICATIONS

This application claims the benefit of U.S. Provisional Application No. 63/689,226, titled “CAPACITIVE READ-OUT MODE FOR FERROELECTRIC FIELD EFFECT TRANSISTOR FOR CHARGE-DOMAIN IN-MEMORY COMPUTING,” filed Aug. 30, 2024, which is incorporated herein by reference in its entirety.

### FEDERALLY SPONSORED RESEARCH AND DEVELOPMENT

This invention was made with government support under Grant No. HR0011-23-3-0002 awarded by the Department of Defense/Defense Advanced Research Projects Agency (DARPA). This invention was also made with government support under Grant No. 2021-21090200003 awarded by the Intelligence Advanced Research Projects Activity (IARPA). The government has certain rights in the invention.

### FIELD OF INVENTION

The present disclosure relates to ferroelectric field effect transistors and in-memory computing architectures, and more particularly to a capacitive read-out operational mode for ferroelectric field effect transistors that enables charge-domain vector-matrix multiplication in capacitive crossbar arrays for artificial intelligence hardware acceleration.

### BACKGROUND

Computing architectures have traditionally separated processing units and memory components, requiring data to be transferred between these distinct elements during computational operations. This separation creates bottlenecks in system throughput and energy efficiency, particularly as data sizes in modern applications continue to grow substantially. The frequent movement of data between processing and storage locations results in increased latency and power consumption, limiting overall system performance.

In-memory computing represents an alternative paradigm that performs computational operations within the same physical location where data is stored. This approach can reduce data transfer requirements and associated energy costs by eliminating the need to repeatedly move information between separate processing and memory units. Various memory technologies have been explored for in-memory computing implementations, including resistive and capacitive approaches.

Resistive crossbar arrays for in-memory computing utilize conductance variations as computational weights in neural network operations. These systems perform vector-matrix multiplication through current-domain computing, where input voltages are applied to word lines and the resulting currents are summed along bit lines. However, resistive approaches face challenges including static power consumption during operation, voltage drops across resistive elements, and sneak-path currents that can affect computational accuracy.

The development of ferroelectric field effect transistors for memory and computing applications faces several significant technical challenges that may limit their practical implementation and performance. Variability issues may arise from the multi-domain nature of ferroelectric materials, where the random distribution and switching behavior of ferroelectric domains can lead to device-to-device variations in electrical characteristics and memory window parameters. Reliability concerns may be associated with the interfacial layer between the semiconductor channel and the ferroelectric layer, where interface trap states, charge trapping, and degradation mechanisms can affect device stability and operational lifetime over extended cycling periods. The relatively high write voltage requirements, typically around 3V for reliable polarization switching, may create compatibility challenges with low-voltage logic circuits and advanced semiconductor nodes that operate at reduced supply voltages. These challenges may necessitate the development of alternative operational approaches and device architectures that can mitigate variability effects, improve reliability characteristics, and reduce voltage requirements while maintaining the non-volatile storage capabilities and computational advantages of ferroelectric-based memory technologies.

The development of ferroelectric random access memory faces significant scaling challenges as the technology advances to smaller semiconductor nodes and higher density requirements. Traditional planar ferroelectric capacitor structures may encounter difficulties in maintaining adequate capacitance values and reliable switching behavior when scaled to nanometer dimensions, potentially compromising memory window margins and operational stability. To address these scaling limitations, advanced three-dimensional capacitor architectures such as cylinder capacitor structures are being developed to increase the effective capacitor area within constrained device footprints. The fabrication complexity increases substantially with these three-dimensional approaches, requiring precise control of multiple processing steps including bottom electrode patterning, ferroelectric material deposition, top electrode formation, crystallization annealing, and subsequent patterning operations. The integration of these complex fabrication sequences with back-end-of-line processing presents additional challenges in terms of thermal budget management, material compatibility, and process yield optimization. These scaling and manufacturing challenges may necessitate continued innovation in device architectures, materials engineering, and fabrication processes to enable ferroelectric random access memory technology to meet the density and performance requirements of advanced memory applications.

Capacitive approaches to in-memory computing offer an alternative methodology that exploits charge-domain computing principles. In such systems, capacitive elements store computational weights, and operations are performed through charge accumulation and redistribution. Capacitive systems can provide advantages including reduced static power consumption, as capacitors primarily consume power during transient switching rather than steady-state operation.

Ferroelectric materials exhibit spontaneous polarization that can be switched between different states through applied electric fields. This property has been utilized in various memory technologies, including ferroelectric random access memory and ferroelectric field effect transistors. Traditional ferroelectric memory operations typically rely on large-signal polarization switching or threshold voltage shifts to distinguish between memory states.

Recent developments in hafnium oxide-based ferroelectric materials have enabled integration with complementary metal-oxide-semiconductor fabrication processes. These materials can be scaled to nanometer dimensions while maintaining ferroelectric properties, making them suitable for advanced semiconductor applications. Various device structures incorporating ferroelectric materials have been demonstrated, including metal-ferroelectric-metal capacitors and ferroelectric field effect transistors.

The development of energy-efficient computing architectures for artificial intelligence applications has become increasingly relevant as computational demands continue to grow. Neural network operations, particularly vector-matrix multiplication, represent computationally intensive tasks that can benefit from specialized hardware implementations. In-memory computing approaches offer potential advantages for these applications by reducing the energy and time associated with data movement between processing and storage elements.

### SUMMARY

The present disclosure provides a method for operating a ferroelectric field effect transistor as a capacitive memory device. The method may comprise connecting a source terminal and a drain terminal of the ferroelectric field effect transistor together, applying a small-signal voltage to a gate terminal of the ferroelectric field effect transistor at zero direct-current gate voltage, and measuring capacitance between the gate terminal and the connected source and drain terminals to determine a capacitance state of the ferroelectric field effect transistor. The capacitance state may correspond to either a high capacitance state or a low capacitance state based on polarization of a ferroelectric gate stack of the ferroelectric field effect transistor.

The capacitance value may be readable in a non-destructive manner by applying a voltage of less than 100 mV. The ferroelectric layer may comprise doped HfO2 based ferroelectric material. The semiconductor layer may comprise silicon substrate, polysilicon, or amorphous oxide semiconductor. In some cases, the amorphous oxide semiconductor may comprise indium oxide with dopants. The device may be configured for front-end-of-line integration or back-end-of-line integration.

The disclosure also provides a non-volatile capacitor device comprising a first metal layer, a ferroelectric layer disposed on the first metal layer, a semiconductor layer disposed on the ferroelectric layer, and a second metal layer disposed on the semiconductor layer. The device may have a tunable analog capacitance value that is programmable by voltage-driven pulses and maintains the capacitance value.

A capacitive array may comprise a plurality of non-volatile capacitor devices arranged in rows and columns, a plurality of word lines coupled to the rows, a plurality of bit lines coupled to the columns, and at least one operational amplifier coupled to the bit lines. The array may be configured to perform vector-matrix multiplication operations and may be configured for charge domain in-memory computing.

The method may further comprise programming a capacitance value of the device by applying voltage-driven pulses to the device, storing the capacitance value in the device without power supply, and reading the capacitance value by applying a voltage of less than 100 mV to the device. The reading may be performed in a non-destructive manner. The method may further comprise erasing the capacitance value by applying voltage-driven pulses of opposite polarity.

A neural network accelerator may comprise a capacitive array and control circuitry configured to program capacitance values of the non-volatile capacitor devices to represent neural network weights, apply input voltages representing neural network inputs to the word lines, and read output signals from the bit lines representing neural network outputs. The control circuitry may be further configured to perform vector-matrix multiplication operations using the capacitive array. The capacitive array may perform charge domain in-memory computing operations.

A system for artificial intelligence acceleration may comprise a plurality of non-volatile capacitor devices configured as synaptic weights and processing circuitry configured to perform neural network computations using the synaptic weights. The neural network computations may comprise machine learning operations.

### BRIEF DESCRIPTION OF FIGURES

Non-limiting and non-exhaustive examples are described with reference to the following figures.

FIGS. 1A-1B illustrate schematic diagrams of a ferroelectric field effect transistor in different capacitive states, according to aspects of the present disclosure.

FIG. 2 illustrates a circuit measurement system for measuring capacitive states of the ferroelectric field effect transistor of FIGS. 1A-1B, according to an embodiment.

FIGS. 3A-3B illustrate capacitance versus gate voltage graphs showing experimental and simulation results, according to aspects of the present disclosure.

FIGS. 4A-4B illustrate an array architecture and bias schemes for a memory array, according to an embodiment.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

The present disclosure relates to a novel operational mode for ferroelectric field effect transistors (FeFETs) that enables capacitive read-out functionality for advanced memory and computing applications. This operational approach represents a departure from conventional resistance-based memory operations, instead leveraging the capacitive properties of FeFET devices to store and retrieve information. The capacitive read-out mode may provide enhanced performance characteristics for in-memory computing architectures, particularly in applications where power efficiency and operational stability are considerations.

The capacitive read-out operational mode for ferroelectric field effect transistors represents a novel approach to memory device operation that leverages the capacitive properties of these devices rather than conventional resistance-based mechanisms. In this operational mode, the memory state may be determined by measuring capacitance variations between terminals of the ferroelectric field effect transistor under specific bias conditions. The approach may enable non-destructive read operations while maintaining the non-volatile characteristics inherent to ferroelectric materials. This operational paradigm may offer advantages in power consumption and operational stability compared to traditional memory access methods.

The capacitive read-out mode may utilize the polarization-dependent capacitance characteristics of ferroelectric materials to create distinguishable memory states. When the ferroelectric layer exhibits different polarization orientations, the resulting capacitance between device terminals may vary in a measurable and reproducible manner. This capacitance variation may serve as the basis for storing and retrieving digital information. The operational approach may eliminate the need for large current flows during read operations, potentially reducing power consumption and improving device longevity.

In-memory computing applications may benefit from the charge-domain computational capabilities enabled by capacitive read-out operations. The capacitive memory elements may participate directly in mathematical operations such as vector-matrix multiplication through charge redistribution mechanisms. This computational approach may allow processing operations to occur within the memory array itself, potentially reducing data movement overhead and improving overall system efficiency. The capacitive nature of the storage elements may enable parallel processing of multiple data elements simultaneously.

The operational mode may support multilevel storage capabilities through controlled polarization states of the ferroelectric material. By applying programming voltages of varying amplitudes, intermediate capacitance states may be achieved between the maximum and minimum capacitance values. This multilevel operation may increase the information density of individual memory cells, allowing storage of multiple bits per device. The programming flexibility may enhance the utility of the devices in applications requiring high-density data storage or analog weight storage for neural network implementations.

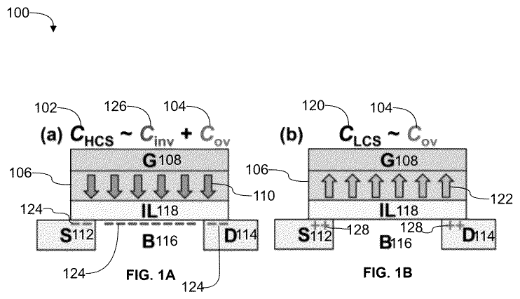

Referring to FIGS. 1A-1B, a ferroelectric field effect transistor 100 may include several structural components that enable capacitive memory operation. The ferroelectric field effect transistor 100 may comprise a semiconductor channel that serves as the conductive pathway for charge carriers during device operation. In some cases, the semiconductor channel may be formed from silicon material, which provides compatibility with conventional semiconductor fabrication processes. The semiconductor channel may alternatively be formed from other semiconductor materials, including oxide semiconductors that may provide compatibility with back-end-of-line fabrication processes.

A ferroelectric layer 106 may be disposed over the semiconductor channel to provide the non-volatile storage functionality of the ferroelectric field effect transistor 100. The ferroelectric layer 106 may comprise doped hafnia materials that exhibit ferroelectric properties at nanoscale dimensions. In some cases, the ferroelectric layer 106 may include silicon-doped hafnium oxide (Si-doped HfO2) or hafnium zirconium oxide (Hf0.5Zr0.5O2) compositions. These ferroelectric materials may provide scalable ferroelectric behavior while maintaining compatibility with complementary metal-oxide-semiconductor fabrication processes. The ferroelectric layer 106 may form part of a ferroelectric gate stack that controls the electrical characteristics of the semiconductor channel.

With continued reference to FIGS. 1A-1B, a gate 108 may be positioned adjacent to the ferroelectric layer 106 to form the ferroelectric gate stack. The gate 108 may be connected to a gate terminal that allows external electrical control of the ferroelectric field effect transistor 100. The ferroelectric gate stack, comprising the ferroelectric layer 106 and the gate 108, may be disposed over the semiconductor channel to enable field-effect control of channel conductivity. The gate 108 may be formed from conductive materials such as metals or doped polysilicon that provide low-resistance electrical contact to the ferroelectric layer 106.

A source 112 and a drain 114 may be connected to the semiconductor channel to provide electrical access points for charge carrier flow. The source 112 and the drain 114 may be formed as doped regions within the semiconductor channel or as separate conductive contacts depending on the specific device architecture. In some cases, the source 112 and the drain 114 may be connected to source and drain terminals respectively that allow external electrical connections to the ferroelectric field effect transistor 100. The positioning of the source 112 and the drain 114 relative to the ferroelectric gate stack may determine the overlap capacitance characteristics of the device during capacitive read-out operations.

As further shown in FIGS. 1A-1B, a body 116 may be present within the ferroelectric field effect transistor 100 structure. The body 116 may comprise the semiconductor material that forms the channel region between the source 112 and the drain 114. In some cases, the body 116 may be connected to a body terminal that allows external electrical control of the substrate potential. The body 116 may alternatively be left as a floating terminal depending on the specific operational requirements of the capacitive memory device. An interfacial layer 118 may be present between the semiconductor channel and the ferroelectric gate stack. The interfacial layer 118 may comprise oxide materials that provide electrical isolation and interface stability between the ferroelectric layer 106 and the underlying semiconductor channel.

The ferroelectric field effect transistor 100 may be implemented using various structural configurations to accommodate different fabrication processes and performance requirements. In some cases, the ferroelectric field effect transistor 100 may have a planar bulk transistor structure where the semiconductor channel is formed within a bulk semiconductor substrate. The planar bulk transistor structure may provide compatibility with conventional planar fabrication processes while enabling integration of the ferroelectric gate stack. Alternatively, the ferroelectric field effect transistor 100 may utilize a silicon-on-insulator transistor structure where the semiconductor channel is formed on an insulating substrate layer. The silicon-on-insulator configuration may provide enhanced electrical isolation and reduced parasitic capacitances compared to bulk implementations.

The ferroelectric field effect transistor 100 may also be implemented as a FinFET structure where the semiconductor channel is formed as a three-dimensional fin-shaped structure. The FinFET configuration may provide improved electrostatic control of the channel region through multi-gate geometry while maintaining compatibility with the ferroelectric gate stack. In some cases, the ferroelectric field effect transistor 100 may utilize a stacked nanosheet transistor structure where multiple semiconductor channel layers are vertically stacked to increase device density. The stacked nanosheet configuration may enable higher integration density while preserving the capacitive read-out functionality of the ferroelectric gate stack.

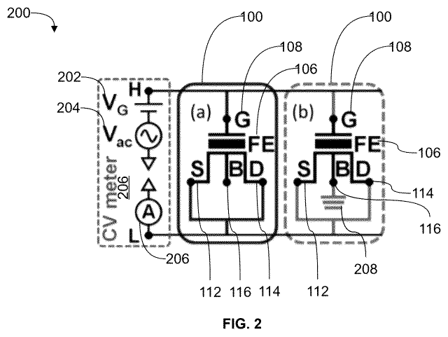

Referring to FIG. 2, a circuit measurement system 200 may be configured to enable capacitive read-out operation of the ferroelectric field effect transistor 100. The circuit measurement system 200 may provide the electrical connections and measurement capabilities for determining the capacitance state of the ferroelectric field effect transistor 100 during memory operations. The capacitive read-out method may involve specific terminal connection configurations and voltage application procedures that differ from conventional transistor operation modes. The circuit measurement system 200 may facilitate measurement of capacitance variations that correspond to different memory states stored within the ferroelectric layer 106 of the ferroelectric field effect transistor 100.

The capacitive read-out operation may begin with connecting the source 112 and the drain 114 of the ferroelectric field effect transistor 100 together to form a combined terminal configuration. This connection arrangement may create a two-terminal capacitive structure where capacitance measurements may be performed between the gate 108 and the combined source-drain terminal. The connection of the source 112 and the drain 114 may eliminate the conventional channel conduction mechanism and instead enable capacitive sensing between the gate terminal and the semiconductor channel region. In some cases, the combined source-drain terminal may serve as one electrode of the capacitive measurement configuration while the gate 108 serves as the opposing electrode.

A voltage source 204 may be incorporated within the circuit measurement system 200 to provide controlled electrical excitation for capacitive measurements. The voltage source 204 may generate a small-signal alternating current voltage that may be applied to the gate 108 of the ferroelectric field effect transistor 100. In some cases, the voltage source 204 may produce sinusoidal voltage waveforms with amplitudes of 0.1 V or less to enable non-destructive capacitance sensing. The small-signal voltage amplitude may be selected to avoid disturbing the polarization state of the ferroelectric layer 106 during read operations. The voltage source 204 may operate at frequencies suitable for capacitance measurement, such as frequencies in the range of 1 MHz or other frequencies that provide adequate measurement sensitivity.

With continued reference to FIG. 2, a gate voltage 202 may be applied to the gate 108 through the voltage source 204 during capacitive read-out operations. The gate voltage 202 may comprise the small-signal alternating current component superimposed on a zero direct-current bias condition. The zero direct-current gate voltage condition may enable measurement of the capacitance state without applying static electric fields that could alter the ferroelectric polarization. In some cases, the gate voltage 202 may be maintained at zero direct-current potential while the small-signal component provides the excitation for capacitance measurement. The gate voltage 202 amplitude may be limited to values that preserve the non-destructive nature of the read operation while providing sufficient signal strength for accurate capacitance determination.

A current meter 206 may be connected within the circuit measurement system 200 to measure the electrical response of the ferroelectric field effect transistor 100 during capacitive read-out operations. The current meter 206 may detect the alternating current flow that results from the capacitive coupling between the gate 108 and the combined source-drain terminal. The magnitude of the measured current may be proportional to the capacitance value and the frequency of the applied gate voltage 202. In some cases, the current meter 206 may be configured as an impedance analyzer or capacitance meter that directly provides capacitance measurements based on the voltage and current relationship. The current meter 206 may provide measurement accuracy sufficient to distinguish between different capacitance states corresponding to different memory values stored in the ferroelectric field effect transistor 100.

As further shown in FIG. 2, the body 116 of the ferroelectric field effect transistor 100 may be configured in different connection states during capacitive read-out operations. In some cases, the body 116 may be connected to a ground 208 to provide a fixed electrical reference potential for the semiconductor substrate. The ground 208 connection may help stabilize the electrical characteristics of the ferroelectric field effect transistor 100 during capacitive measurements by providing a defined potential for the body region. Alternatively, the body 116 may be left as a floating terminal that is not connected to any external voltage source or ground reference. The floating body configuration may reduce parasitic capacitances and electrical interference that could affect the accuracy of capacitive measurements between the gate 108 and the combined source-drain terminal.

The capacitive read-out method may enable determination of the memory state stored within the ferroelectric field effect transistor 100 based on the measured capacitance value. The capacitance state may correspond to either a high capacitance state or a low capacitance state depending on the polarization orientation of the ferroelectric layer 106 within the ferroelectric gate stack. When the ferroelectric layer 106 exhibits one polarization direction, the resulting capacitance between the gate 108 and the combined source-drain terminal may correspond to the high capacitance state. Conversely, when the ferroelectric layer 106 exhibits the opposite polarization direction, the measured capacitance may correspond to the low capacitance state. The circuit measurement system 200 may provide the measurement sensitivity to reliably distinguish between these different capacitance states during memory read operations.

The operational parameters of the capacitive read-out method may be selected to achieve reliable and repeatable capacitance sensing while preserving the non-volatile memory characteristics of the ferroelectric field effect transistor 100. The small-signal voltage amplitude applied through the voltage source 204 may be maintained at levels that do not cause unwanted polarization switching in the ferroelectric layer 106. In some cases, voltage amplitudes of 0.1 V or less may provide adequate measurement signal while avoiding disturbance of the stored memory state. The measurement frequency and duration may be selected to provide sufficient signal-to-noise ratio for accurate capacitance determination while minimizing any potential degradation effects on the ferroelectric material properties.

Programming operations may be performed on the ferroelectric field effect transistor to establish the high capacitance state through controlled application of electrical signals to the gate terminal. The programming procedure may involve applying a positive gate voltage pulse of sufficient amplitude to induce polarization switching within the ferroelectric gate stack. The positive gate voltage pulse may create an electric field across the ferroelectric layer that exceeds the coercive field threshold, causing the ferroelectric domains to align in a specific orientation. In some cases, the programming voltage amplitude may be selected to ensure complete polarization switching while avoiding excessive stress on the ferroelectric material that could lead to degradation or reliability issues.

The amplitude of the programming voltage pulse may vary depending on the specific ferroelectric material composition and thickness of the ferroelectric gate stack. In some cases, programming voltages as low as +3.5V may provide sufficient electric field strength to achieve reliable polarization switching in doped hafnia ferroelectric layers. The programming voltage amplitude may alternatively be set to higher values when thicker ferroelectric layers or materials with higher coercive fields are utilized. The duration of the programming voltage pulse may be selected to allow adequate time for domain switching while minimizing energy consumption and potential stress effects on the device structure.

Erasing operations may be performed to establish the low capacitance state through application of voltage pulses with polarity opposite to the programming operation. The erasing procedure may involve applying a negative gate voltage pulse of sufficient amplitude to reverse the polarization orientation within the ferroelectric gate stack. The negative gate voltage pulse may create an electric field that causes the ferroelectric domains to switch to the opposite alignment compared to the programmed state. In some cases, the erasing voltage amplitude may be approximately equal in magnitude to the programming voltage but with reversed polarity to ensure symmetric switching behavior. The erasing voltage pulse may utilize amplitudes such as −3.5V or other sufficiently large negative values to achieve complete polarization reversal.

The programming and erasing voltage amplitudes may be adjusted to achieve partial polarization of the ferroelectric gate stack, enabling multilevel cell operation capabilities. Partial polarization may be accomplished by applying voltage pulses with amplitudes that are intermediate between the threshold voltage for domain switching and the saturation voltage for complete polarization. When partial polarization occurs, only a fraction of the ferroelectric domains within the gate stack may switch orientation, resulting in intermediate capacitance states between the maximum high capacitance state and the minimum low capacitance state. The degree of partial polarization may be controlled by precisely adjusting the amplitude, duration, or waveform shape of the applied voltage pulses.

Multilevel cell operation may enable storage of more than 1 bit per transistor cell through the creation of multiple distinguishable capacitance levels. In some cases, four distinct capacitance states may be achieved through controlled partial polarization, allowing storage of 2 bits of information per device. The intermediate capacitance states may be programmed by applying voltage pulses with amplitudes that fall between the threshold values for different degrees of domain switching. The multilevel programming approach may require precise control of the voltage pulse characteristics to ensure repeatable and stable intermediate states that can be reliably distinguished during read operations.

The voltage pulse characteristics for programming and erasing operations may be optimized to balance switching reliability with device longevity and power consumption considerations. The pulse duration may be selected to provide adequate time for domain nucleation and growth while minimizing the total energy required for switching operations. In some cases, shorter pulse durations may reduce power consumption but may require higher voltage amplitudes to achieve reliable switching. The pulse rise and fall times may be controlled to minimize overshoot effects that could cause unwanted over-polarization or stress on the ferroelectric material. The repetition rate of programming and erasing operations may be limited to allow recovery time for the ferroelectric domains and to prevent cumulative stress effects that could degrade device performance over extended operation cycles.

Referring to FIGS. 1A-1B, the capacitive read-out operation of the ferroelectric field effect transistor 100 may be understood through the underlying physical mechanisms that create distinguishable capacitance states based on the polarization orientation of the ferroelectric layer 106. The capacitive behavior may result from the interaction between the ferroelectric polarization and the charge distribution within the semiconductor channel region. When different polarization states are established within the ferroelectric layer 106, the resulting electric field distribution and charge carrier behavior may create measurably different capacitance values between the gate 108 and the combined source 112 and drain 114 terminals. These capacitance variations may form the basis for non-volatile memory operation through the capacitive read-out method.

As shown in FIG. 1A, a high capacitance state 102 may be established when the ferroelectric layer 106 exhibits a polarization orientation that induces specific charge distributions within the semiconductor channel. In the high capacitance state 102, an electric field 110 may extend from the gate 108 through the ferroelectric layer 106 and the interfacial layer 118 into the body 116 region. The electric field 110 may create conditions that promote the accumulation of negative charges 124 within the semiconductor channel region adjacent to the interfacial layer 118. The presence of the negative charges 124 may establish an inversion layer within the semiconductor channel when the ferroelectric field effect transistor 100 operates at zero direct-current gate voltage conditions. The inversion layer formation may enable the creation of an inversion capacitance 126 that contributes to the overall capacitance measured between the gate 108 and the combined source 112 and drain 114 terminals.

The inversion capacitance 126 may dominate the capacitive behavior of the ferroelectric field effect transistor 100 when the semiconductor channel operates in inversion mode at zero direct-current gate voltage. The inversion capacitance 126 may be proportional to the gate area, which corresponds to the product of the channel width and the channel length of the ferroelectric field effect transistor 100. When the semiconductor channel is in inversion mode, the entire gate area may contribute to the capacitive coupling between the gate 108 and the semiconductor channel region. The magnitude of the inversion capacitance 126 may depend on the thickness and dielectric properties of the ferroelectric layer 106 and the interfacial layer 118, as well as the charge density within the inversion layer. The inversion capacitance 126 may provide the larger capacitance value that characterizes the high capacitance state 102 during capacitive read-out operations.

With continued reference to FIG. 1B, a low capacitance state 120 may be established when the ferroelectric layer 106 exhibits the opposite polarization orientation compared to the high capacitance state 102 configuration. In the low capacitance state 120, an electric field 122 may extend from the gate 108 through the ferroelectric layer 106 and the interfacial layer 118 with a direction that differs from the electric field 110 present in the high capacitance state 102. The electric field 122 may create conditions that promote the accumulation of positive charges 128 within the semiconductor channel region. The presence of the positive charges 128 may establish a depletion or accumulation region within the semiconductor channel when the ferroelectric field effect transistor 100 operates at zero direct-current gate voltage conditions. The depletion mode operation may eliminate the inversion layer that was present in the high capacitance state 102, thereby reducing the contribution of the inversion capacitance 126 to the overall measured capacitance.

When the semiconductor channel operates in depletion mode at zero direct-current gate voltage, an overlap capacitance 104 may dominate the capacitive behavior of the ferroelectric field effect transistor 100. The overlap capacitance 104 may result from the capacitive coupling between the gate 108 and the source 112 and drain 114 regions through the overlap areas where the gate 108 extends over the source 112 and drain 114 terminals. The overlap capacitance 104 may be proportional to the overlap area between the gate 108 and the source 112 and drain 114 regions, rather than the total gate area as was the case for the inversion capacitance 126. The overlap capacitance 104 may provide a smaller capacitance value compared to the inversion capacitance 126 because the overlap area may be smaller than the total gate area. The overlap capacitance 104 may characterize the low capacitance state 120 during capacitive read-out operations when the semiconductor channel is in depletion mode.

The capacitance on/off ratio between the high capacitance state 102 and the low capacitance state 120 may be determined by the relative magnitudes of the inversion capacitance 126 and the overlap capacitance 104. In some cases, the capacitance on/off ratio may exceed values greater than 20, providing substantial differentiation between the two memory states during capacitive read-out operations. The capacitance on/off ratio may be proportional to the ratio of the gate area to the overlap area between the gate 108 and the source 112 and drain 114 terminals. When the gate area is large relative to the overlap area, the inversion capacitance 126 may be substantially larger than the overlap capacitance 104, resulting in a higher capacitance on/off ratio. Conversely, when the overlap area approaches the gate area in magnitude, the capacitance on/off ratio may be reduced due to the smaller difference between the inversion capacitance 126 and the overlap capacitance 104.

As further shown in FIGS. 1A-1B, the device geometry of the ferroelectric field effect transistor 100 may influence the capacitance on/off ratio through the relationship between the channel dimensions and the overlap dimensions. The capacitance on/off ratio may be improved by engineering the ferroelectric field effect transistor 100 geometry to enlarge the ratio between the channel length and the overlap length. When the channel length is increased relative to the overlap length, the gate area may increase proportionally while the overlap area may remain relatively constant. This geometric relationship may enhance the inversion capacitance 126 contribution in the high capacitance state 102 while maintaining the overlap capacitance 104 at a lower level in the low capacitance state 120. The resulting increase in the capacitance on/off ratio may improve the signal margin and measurement reliability during capacitive read-out operations.

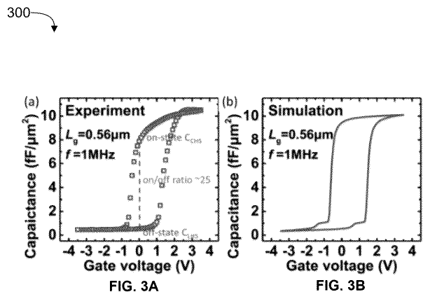

Referring to FIGS. 3A and 3B, experimental and simulation results may demonstrate the capacitive behavior of the ferroelectric field effect transistor 100 under different polarization conditions. The experimental measurements shown in FIG. 3A may illustrate the capacitance-voltage characteristics of a ferroelectric field effect transistor 100 with a gate length of 0.56 micrometers operating at a frequency of 1 MHz. The measured capacitance values may exhibit hysteretic behavior that corresponds to the different polarization states of the ferroelectric layer 106. The high capacitance state 102 may be observed when the ferroelectric layer 106 is polarized in one direction, while the low capacitance state 120 may be observed when the ferroelectric layer 106 is polarized in the opposite direction. The capacitance on/off ratio demonstrated in the experimental results may approach approximately 25, confirming the substantial differentiation between the two capacitance states.

The simulation results presented in FIG. 3B may provide theoretical validation of the physical mechanisms underlying the capacitive read-out operation. The simulated capacitance-voltage characteristics may reproduce the hysteretic behavior observed in the experimental measurements, confirming the accuracy of the physical models used to describe the ferroelectric field effect transistor 100 operation. The simulation results may demonstrate that the inversion capacitance 126 dominates the high capacitance state 102 when the semiconductor channel is in inversion mode, while the overlap capacitance 104 dominates the low capacitance state 120 when the semiconductor channel is in depletion mode. The agreement between experimental and simulation results may validate the understanding of the physical mechanisms that enable capacitive read-out functionality in ferroelectric field effect transistor 100 devices.

The gate metal work function may provide an additional parameter for engineering the capacitance on/off ratio while maintaining the device dimensions of the ferroelectric field effect transistor 100. The work function of the gate 108 material may influence the threshold voltage characteristics and the electric field distribution within the ferroelectric gate stack. By selecting gate 108 materials with appropriate work function values, the voltage conditions for achieving inversion and depletion modes may be optimized to maximize the difference between the inversion capacitance 126 and the overlap capacitance 104. The work function engineering approach may enable further increases in the capacitance on/off ratio without requiring changes to the physical dimensions or geometry of the ferroelectric field effect transistor 100. In some cases, the work function optimization may allow achievement of capacitance on/off ratios exceeding 100 through careful selection of gate 108 materials and ferroelectric layer 106 compositions.

The fabrication of ferroelectric field effect transistors with capacitive read-out capability may be accomplished through various manufacturing approaches that accommodate different integration requirements and performance objectives. The manufacturing processes may be categorized into front-end-of-line and back-end-of-line fabrication methodologies, each offering distinct advantages for specific application contexts. The selection of fabrication approach may depend on factors such as thermal budget constraints, material compatibility requirements, and integration density objectives. Manufacturing considerations may include the deposition and crystallization of ferroelectric materials, electrode formation processes, and interface engineering techniques that preserve the capacitive sensing functionality.

Front-end-of-line fabrication processes may enable integration of ferroelectric field effect transistors directly within the primary transistor formation sequence of semiconductor manufacturing. The front-end-of-line approach may utilize foundry-compatible processes that allow incorporation of ferroelectric gate stacks during the standard transistor fabrication flow. In some cases, the ferroelectric layer deposition may occur after gate electrode formation but before source and drain implantation steps. The front-end-of-line process may involve atomic layer deposition techniques for forming uniform ferroelectric layers with controlled thickness and composition. The deposition temperature and ambient conditions may be selected to promote the formation of ferroelectric phases while maintaining compatibility with existing semiconductor processing equipment.

The foundry front-end-of-line fabrication process may incorporate ferroelectric materials such as doped hafnia compositions into conventional complementary metal-oxide-semiconductor manufacturing flows. The process may begin with standard substrate preparation and isolation formation steps that establish the device regions for transistor fabrication. Gate oxide formation may be followed by ferroelectric layer deposition using atomic layer deposition or chemical vapor deposition techniques. The ferroelectric layer thickness may be controlled to achieve the desired capacitive properties while maintaining adequate breakdown voltage characteristics. Crystallization annealing processes may be applied to promote the formation of ferroelectric phases within the deposited hafnia-based materials.

Gate electrode formation in the front-end-of-line process may involve deposition of conductive materials such as titanium nitride, tungsten, or polysilicon that provide low-resistance contact to the ferroelectric layer. The gate electrode material selection may consider work function requirements that optimize the threshold voltage characteristics for capacitive read-out operation. Patterning processes may define the gate dimensions and alignment relative to the source and drain regions. The gate patterning may control the overlap areas between the gate electrode and the source and drain regions, which may influence the capacitive on/off ratio during read-out operations. Etching processes may be optimized to preserve the ferroelectric layer integrity while achieving precise gate electrode dimensions.

Source and drain formation in the front-end-of-line process may utilize ion implantation techniques that introduce dopant atoms into the semiconductor substrate adjacent to the gate electrode regions. The implantation energy and dose may be selected to achieve the desired junction depth and dopant concentration while avoiding damage to the ferroelectric gate stack. Activation annealing processes may be applied to repair implantation damage and activate the implanted dopants. The annealing temperature and duration may be controlled to prevent degradation of the ferroelectric properties while achieving adequate source and drain conductivity. Silicide formation processes may be applied to reduce the contact resistance between metal interconnects and the source and drain regions.

Back-end-of-line fabrication processes may enable integration of ferroelectric field effect transistors within the metallization layers of semiconductor devices, providing opportunities for three-dimensional integration and reduced thermal budget requirements. The back-end-of-line approach may utilize thin-film transistor structures where the semiconductor channel is formed from deposited materials rather than the bulk semiconductor substrate. In some cases, oxide semiconductor materials such as indium gallium zinc oxide or tungsten-doped indium oxide may serve as the channel material in back-end-of-line ferroelectric field effect transistors. The oxide semiconductor deposition may occur at temperatures compatible with existing metallization processes, allowing integration above conventional silicon transistors.

The back-end-of-line fabrication process may begin with the formation of a planarized dielectric layer that provides the foundation for thin-film transistor construction. The dielectric layer may comprise materials such as silicon dioxide or low-k dielectric materials that provide electrical isolation from underlying circuit elements. Channel material deposition may utilize sputtering or atomic layer deposition techniques to form uniform semiconductor layers with controlled thickness and composition. The channel material may be patterned using photolithography and etching processes to define the transistor active regions. The channel dimensions may be selected to achieve the desired capacitive properties while maintaining adequate current handling capability for programming and erasing operations.

Ferroelectric layer formation in the back-end-of-line process may utilize deposition techniques that are compatible with the thermal constraints of metallization processing. Atomic layer deposition may provide precise thickness control and conformality for ferroelectric layers deposited over the thin-film channel regions. The deposition temperature may be limited to values that prevent degradation of underlying metallization layers while enabling formation of ferroelectric phases. In some cases, post-deposition annealing processes may be applied to enhance the ferroelectric properties through controlled crystallization. The annealing temperature and ambient may be optimized to promote ferroelectric phase formation while maintaining compatibility with back-end-of-line thermal budgets.

Gate electrode formation in the back-end-of-line process may utilize metal deposition techniques that provide low-resistance contact to the ferroelectric layer while maintaining compatibility with interconnect processing. The gate electrode material may be selected from metals such as titanium, titanium nitride, or tungsten that offer appropriate work function characteristics and thermal stability. Patterning processes may define the gate electrode geometry and alignment relative to the thin-film channel regions. The gate electrode dimensions may be controlled to optimize the overlap areas with source and drain contacts, thereby influencing the capacitive sensing characteristics during read-out operations.

Source and drain contact formation in the back-end-of-line process may involve direct metal contact to the thin-film semiconductor channel without requiring ion implantation processes. The contact metals may be selected to provide low-resistance ohmic contact to the channel material while maintaining thermal stability during subsequent processing steps. Contact patterning may define the source and drain regions and establish the channel length between the contacts. The contact geometry may influence the overlap capacitance characteristics that contribute to the low capacitance state during capacitive read-out operations. Via formation processes may provide electrical connection between the thin-film transistor terminals and the surrounding metallization layers.

Manufacturing considerations for both front-end-of-line and back-end-of-line processes may include interface engineering techniques that optimize the electrical characteristics of the ferroelectric gate stack. Interfacial layer formation may involve controlled oxidation or deposition processes that create stable interfaces between the ferroelectric material and the semiconductor channel. The interfacial layer thickness and composition may influence the capacitive coupling efficiency and the voltage scaling characteristics of the ferroelectric field effect transistor. Surface preparation techniques may be applied to minimize interface trap density and promote uniform ferroelectric layer nucleation.

Process compatibility requirements may encompass thermal budget limitations, chemical compatibility constraints, and contamination control measures that preserve the functionality of both the ferroelectric elements and the surrounding circuit components. The thermal processing steps may be sequenced to minimize exposure of temperature-sensitive materials while achieving adequate ferroelectric crystallization and interface formation.

Chemical compatibility may be maintained through appropriate selection of etchants, cleaning solutions, and deposition precursors that do not degrade ferroelectric properties or introduce unwanted impurities. Contamination control measures may include dedicated processing equipment and specialized handling procedures that prevent cross-contamination between ferroelectric processing steps and conventional semiconductor processing operations.

Quality control and characterization techniques may be integrated into the fabrication processes to monitor ferroelectric properties and capacitive sensing functionality throughout manufacturing. Electrical testing may be performed at various process stages to verify ferroelectric switching behavior, capacitive on/off ratios, and device yield characteristics. Structural characterization techniques such as X-ray diffraction or transmission electron microscopy may be utilized to confirm ferroelectric phase formation and interface quality. Process monitoring may enable feedback control of deposition parameters, annealing conditions, and patterning processes to maintain consistent device performance across manufacturing lots.

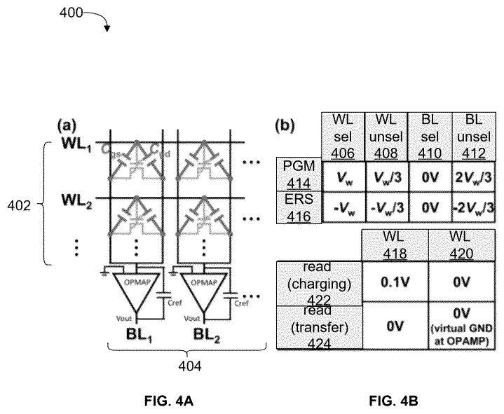

Referring to FIGS. 4A and 4B, a memory array 400 may be configured to organize multiple ferroelectric field effect transistors into a capacitive crossbar architecture that enables in-memory computing applications. The memory array 400 may comprise a plurality of ferroelectric field effect transistor cells arranged in rows and columns to form a two-dimensional grid structure. Each ferroelectric field effect transistor cell within the memory array 400 may be configured to store a capacitive weight value through the polarization state of the ferroelectric layer within the device. The capacitive weight values may correspond to synaptic weights or other numerical parameters that participate in computational operations such as vector-matrix multiplication. The memory array 400 may enable parallel processing of multiple data elements through simultaneous access to numerous ferroelectric field effect transistor cells during computational operations.

The ferroelectric field effect transistor cells within the memory array 400 may operate in the capacitive read-out mode described previously, where the capacitance between the gate and the combined source and drain terminals determines the stored weight value. Each ferroelectric field effect transistor cell may exhibit either the high capacitance state or the low capacitance state depending on the polarization orientation of the ferroelectric layer within the device. The capacitance on/off ratio between these states may exceed values greater than 20, providing adequate signal differentiation for reliable weight storage and retrieval operations. The memory array 400 may be scaled to accommodate hundreds by hundreds of ferroelectric field effect transistor cells, enabling storage of large weight matrices for complex computational tasks such as neural network inference operations.

With continued reference to FIG. A, a wordline group 402 may provide horizontal electrical connections that link the gate terminals of ferroelectric field effect transistor cells within each row of the memory array 400. The wordline group 402 may comprise multiple individual wordlines, each corresponding to a specific row within the memory array 400. The wordlines within the wordline group 402 may be formed from conductive materials such as metals or doped polysilicon that provide low-resistance electrical paths for applying control voltages to the gate terminals of the ferroelectric field effect transistor cells. The wordline group 402 may enable simultaneous control of all ferroelectric field effect transistor cells within a selected row during programming, erasing, or reading operations. The wordlines may be routed to peripheral driver circuits that generate the appropriate voltage levels for different operational modes of the memory array 400.

A bitline group 404 may provide vertical electrical connections that link the source and drain terminals of ferroelectric field effect transistor cells within each column of the memory array 400. The bitline group 404 may comprise multiple individual bitlines, each corresponding to a specific column within the memory array 400. The source and drain terminals of each ferroelectric field effect transistor cell may be connected together and then coupled to the corresponding bitline within the bitline group 404. This connection configuration may enable the capacitive read-out mode operation where capacitance measurements are performed between the wordlines and the bitlines. The bitline group 404 may facilitate charge accumulation and transfer operations during computational phases of in-memory computing operations. The bitlines may extend to peripheral sensing circuits that detect and process the electrical signals generated during capacitive read-out operations.

As further shown in FIG. A, peripheral circuits may be integrated at the end of each bitline within the bitline group 404 to provide signal processing and computational capabilities for the memory array 400. The peripheral circuits may include operational amplifiers that serve as charge integrators and voltage amplifiers during capacitive sensing operations. Each operational amplifier may be connected to a reference capacitor that determines the voltage gain and signal scaling characteristics during charge transfer operations. The operational amplifiers may provide virtual ground connections for the bitlines during specific phases of the computational operations, enabling controlled charge redistribution from the ferroelectric field effect transistor cells to the reference capacitors. The peripheral circuits may also include analog-to-digital converters that quantize the analog voltage outputs from the operational amplifiers into digital values for further processing by digital circuits.

The operational amplifiers within the peripheral circuits may enable charge-domain computing operations through controlled charge accumulation and transfer processes. During computational operations, the ferroelectric field effect transistor cells may be charged through the wordlines while the bitlines are maintained at ground potential. The charge stored on each ferroelectric field effect transistor cell may be proportional to the product of the applied wordline voltage and the capacitance value stored within the cell. Subsequently, the accumulated charges may be transferred from the ferroelectric field effect transistor cells to the operational amplifiers through the bitlines. The operational amplifiers may integrate the transferred charges and generate output voltages that represent the weighted sum of the input voltages applied to the wordlines. This charge-domain computational approach may enable parallel vector-matrix multiplication operations within the memory array 400.

The vector-matrix multiplication process enabled by capacitive crossbar arrays may utilize charge preservation and redistribution principles to perform computational operations directly within the memory structure. This charge-domain computing approach may represent a fundamental departure from conventional digital arithmetic methods, instead leveraging the physical properties of capacitive storage elements to execute mathematical operations through controlled electrical processes. The computational methodology may involve coordinated voltage applications and charge sensing procedures that enable parallel processing of multiple input-output relationships simultaneously. The charge-domain approach may provide computational efficiency advantages compared to traditional approaches that require separate multiplication and accumulation circuits for each arithmetic operation.

The vector-matrix multiplication operation may be implemented through a two-phase process that separates the multiplication and accumulation functions into distinct temporal phases. During the first phase, known as the charging phase, the ferroelectric capacitor array storing the weight values may be charged with wordline voltages that represent the input vector components. Each individual capacitor within the array may accumulate charge according to the relationship Q_FE=V_WL×C_FE, where the stored charge becomes proportional to both the applied input voltage and the programmed capacitance value of the ferroelectric device. This charging process may occur simultaneously across all activated wordlines and their associated capacitive elements, enabling parallel multiplication operations where each capacitor performs an individual multiplication between its stored weight value and the corresponding input voltage component.

The second phase, referred to as the transfer and summation phase, may enable the extraction and combination of the accumulated charges to produce the final computational results. During this phase, all charges stored on ferroelectric capacitors within each bitline column may be transferred and summed through connections to operational amplifiers equipped with reference capacitors. The operational amplifiers may convert the accumulated charge quantities into proportional output voltages according to the relationship V_out,j=(Σ V_in, i×C_FE,i,j)/C_ref, where the summation occurs over all row indices i for each column j. This charge-to-voltage conversion process may enable the direct readout of dot-product computational results, with each operational amplifier output representing the weighted sum of input voltages and stored weight values for its corresponding column. The parallel nature of this charge accumulation and conversion process may enable simultaneous computation of multiple output vector components, providing computational throughput that scales with the array dimensions and the number of simultaneously activated input channels.

Referring to FIG. B, the memory array 400 may be configured to support various operational modes through specific bias schemes applied to the wordline group 402 and the bitline group 404. The bias schemes may include programming operations, erasing operations, and reading operations that enable storage, modification, and retrieval of capacitive weight values within the ferroelectric field effect transistor cells. Each operational mode may utilize different voltage levels and connection configurations to achieve the desired electrical conditions for reliable device operation. The bias schemes may be designed to minimize interference between selected and unselected cells during individual cell operations while maintaining the stored weight values in non-selected cells.

Programming operations may be performed to establish specific capacitance states within selected ferroelectric field effect transistor cells through controlled application of voltage pulses. During programming operations, a selected wordline 406 may be biased with a write voltage that provides sufficient electric field strength to induce polarization switching within the ferroelectric layer of the target cells. The write voltage amplitude may be selected to exceed the coercive field threshold of the ferroelectric material while avoiding excessive stress that could degrade device reliability. A selected bitline 410 may be connected to ground potential to establish the voltage difference across the selected ferroelectric field effect transistor cells. Unselected wordlines 408 within the wordline group 402 may be biased at one-third of the write voltage to reduce the electric field applied to non-selected cells and prevent unwanted programming operations. Similarly, unselected bitlines 412 within the bitline group 404 may be biased at two-thirds of the write voltage to further minimize the voltage difference across non-selected cells.

Erasing operations may be performed to establish the opposite capacitance state within selected ferroelectric field effect transistor cells through application of voltage pulses with reversed polarity compared to programming operations. During erasing operations, the selected wordline 406 may be biased with a reversed write voltage that creates an electric field with opposite polarity to the programming condition. The reversed write voltage amplitude may be approximately equal in magnitude to the programming voltage but with negative polarity to ensure symmetric switching behavior. The selected bitline 410 may be maintained at ground potential to establish the voltage difference for polarization reversal. The unselected wordlines 408 may be biased at negative one-third of the write voltage, while the unselected bitlines 412 may be biased at negative two-thirds of the write voltage. This bias scheme may prevent unwanted erasing operations in non-selected cells while enabling reliable polarization switching in the target cells.

Reading operations may be performed through a two-phase process that enables charge-domain computational operations within the memory array 400. The reading operations may include a charging phase and a transfer phase that work together to perform vector-matrix multiplication computations using the stored capacitive weight values. During the charging phase, a charging wordline 418 may be biased with a small voltage, such as 0.1 V, that provides adequate signal strength for capacitive sensing without disturbing the stored polarization states. The charging operation 422 may involve applying the small voltage to selected wordlines while maintaining the bitlines at ground potential. This voltage configuration may cause charge accumulation on the ferroelectric field effect transistor cells proportional to the product of the applied voltage and the stored capacitance values.

The transfer phase of the reading operation may enable extraction of the accumulated charges from the ferroelectric field effect transistor cells and conversion to voltage signals through the peripheral circuits. During the transfer phase, a transfer wordline 420 may be connected to ground potential to eliminate the charging voltage from the ferroelectric field effect transistor cells. The transfer operation 424 may involve connecting the bitlines to virtual ground through the operational amplifiers within the peripheral circuits. The charge stored on each ferroelectric field effect transistor cell may be transferred to the reference capacitors connected to the operational amplifiers, generating output voltages proportional to the accumulated charge quantities. The output voltages may represent the dot-product computational result of the wordline input voltage vector and the capacitive weight matrix pattern stored within the memory array 400.

The memory array 400 may be organized in an AND array architecture where the ferroelectric field effect transistor cells are directly connected between the wordlines and bitlines without additional access transistors. The AND array architecture may provide compact cell area and high integration density compared to architectures that require separate access devices for each memory cell. The direct connection between the ferroelectric field effect transistor cells and the wordlines and bitlines may enable efficient charge transfer during computational operations while minimizing parasitic capacitances and resistance losses. The AND array architecture may support parallel access to multiple cells during vector-matrix multiplication operations, enabling high computational throughput for in-memory computing applications.

The scalability of the memory array 400 may accommodate large-scale integration of ferroelectric field effect transistor cells to support complex computational tasks such as deep neural network inference operations. The memory array 400 may be configured with hundreds of rows and hundreds of columns, providing storage capacity for weight matrices containing tens of thousands of individual weight values. The high capacitance on/off ratio of the ferroelectric field effect transistor cells may enable reliable operation of large arrays by providing adequate signal margins for distinguishing between different capacitance states. The peripheral circuits may be designed to handle the increased signal processing requirements associated with large array sizes while maintaining computational accuracy and speed performance.

Referring to FIGS. 4A and 4B, the memory array 400 may be configured to support multiple operational modes through specific voltage application schemes that enable reliable storage, modification, and retrieval of capacitive weight values within the ferroelectric field effect transistor cells. The operational modes may include programming procedures that establish specific polarization states, erasing procedures that reverse polarization orientations, and reading procedures that extract stored information through capacitive sensing mechanisms. Each operational mode may utilize distinct voltage levels and timing sequences applied to the wordline group 402 and the bitline group 404 to achieve the desired electrical conditions across the selected ferroelectric field effect transistor cells while minimizing interference with non-selected devices. The voltage application schemes may be designed to provide adequate signal margins for reliable operation while preventing unwanted switching or degradation in adjacent cells within the memory array 400.

A program mode 414 may be implemented to establish the high capacitance state within selected ferroelectric field effect transistor cells through controlled application of programming voltage pulses to the appropriate wordlines and bitlines. During the program mode 414, the selected wordline 406 may receive a write voltage that provides sufficient electric field strength to induce polarization switching within the ferroelectric layer 106 of the target cells. The write voltage amplitude may be selected to exceed the coercive field threshold of the ferroelectric material while maintaining compatibility with the voltage handling capabilities of the peripheral circuits and interconnect structures. The selected bitline 410 may be connected to ground potential to establish the voltage difference across the selected ferroelectric field effect transistor cells, creating the electric field conditions for reliable polarization switching toward the high capacitance state configuration.

With continued reference to FIG. B, an unselected wordline 408 within the wordline group 402 may be biased at one-third of the write voltage during the program mode 414 to reduce the electric field applied to non-selected ferroelectric field effect transistor cells. The reduced voltage level on the unselected wordline 408 may prevent unwanted programming operations in cells that share the same bitline as the selected cell but are located in different rows of the memory array 400. An unselected bitline 412 within the bitline group 404 may be biased at two-thirds of the write voltage to further minimize the voltage difference across non-selected cells that share the same wordline as the selected cell. The combination of the reduced voltage on the unselected wordline 408 and the elevated voltage on the unselected bitline 412 may result in a net voltage difference that remains below the coercive field threshold, thereby preserving the existing polarization states in non-selected ferroelectric field effect transistor cells.

An erase mode 416 may be implemented to establish the low capacitance state within selected ferroelectric field effect transistor cells through application of voltage pulses with polarity opposite to the program mode 414 conditions. During the erase mode 416, the selected wordline 406 may receive a reversed write voltage that creates an electric field with opposite polarity compared to the programming condition. The reversed write voltage amplitude may be approximately equal in magnitude to the programming voltage but with negative polarity to ensure symmetric switching behavior and reliable polarization reversal within the ferroelectric layer 106. The selected bitline 410 may be maintained at ground potential to establish the voltage difference for inducing polarization switching toward the low capacitance state configuration. The electric field created during the erase mode 416 may cause the ferroelectric domains within the selected cells to switch to the opposite alignment compared to the programmed state.

The voltage application scheme during the erase mode 416 may incorporate bias conditions for non-selected cells that prevent unwanted erasing operations while enabling reliable polarization switching in the target cells. The unselected wordline 408 may be biased at negative one-third of the write voltage to reduce the electric field magnitude applied to non-selected ferroelectric field effect transistor cells that share the same bitline as the selected cell. The unselected bitline 412 may be biased at negative two-thirds of the write voltage to minimize the voltage difference across non-selected cells that share the same wordline as the selected cell. The combination of these bias voltages may ensure that the net electric field across non-selected cells remains below the threshold for polarization switching, thereby maintaining the stored capacitive weight values in cells that are not targeted for erasing operations.

As further shown in FIG. B, reading operations within the memory array 400 may be performed through a two-phase process that enables charge-domain computational operations using the stored capacitive weight values within the ferroelectric field effect transistor cells. The two-phase reading approach may separate the charge accumulation process from the charge transfer and signal conversion processes, allowing precise control of the computational timing and signal integrity. The first phase may involve charging the ferroelectric field effect transistor cells with input voltage signals applied through the wordline group 402, while the second phase may involve transferring the accumulated charges to the peripheral circuits through the bitline group 404. The two-phase operation may enable vector-matrix multiplication computations where the input voltage vector is applied during the charging phase and the weighted sum results are extracted during the transfer phase.

The charging phase of the reading operation may involve application of small voltage signals to selected wordlines while maintaining the bitlines at ground potential to enable charge accumulation on the ferroelectric field effect transistor cells. During the charging operation 422, the charging wordline 418 may be biased with a small voltage amplitude, such as 0.1 V, that provides adequate signal strength for capacitive sensing without disturbing the stored polarization states within the ferroelectric layer 106. The small voltage amplitude may be selected to remain well below the coercive field threshold of the ferroelectric material, ensuring that the reading operation does not alter the stored capacitive weight values. The bitlines within the bitline group 404 may be maintained at ground potential during the charging phase to establish the voltage difference across the ferroelectric field effect transistor cells. The charge accumulated on each cell may be proportional to the product of the applied wordline voltage and the capacitance value stored within the ferroelectric field effect transistor, creating the basis for multiplication operations in the charge domain.

The transfer phase of the reading operation may enable extraction of the accumulated charges from the ferroelectric field effect transistor cells and conversion to voltage signals through the operational amplifiers within the peripheral circuits. During the transfer operation 424, the transfer wordline 420 may be connected to ground potential to eliminate the charging voltage from the ferroelectric field effect transistor cells and enable charge redistribution to the peripheral circuits. The bitlines within the bitline group 404 may be connected to virtual ground through the operational amplifiers, creating a low-impedance path for charge transfer from the ferroelectric field effect transistor cells to the reference capacitors connected to the operational amplifiers. The charge stored on each ferroelectric field effect transistor cell may flow through the corresponding bitline to the operational amplifier, where the charge may be integrated by the reference capacitor to generate an output voltage proportional to the accumulated charge quantity.

The charge transfer mechanism during the transfer operation 424 may enable summation of charges from multiple ferroelectric field effect transistor cells within each column of the memory array 400, thereby performing the accumulation operation for vector-matrix multiplication computations. When multiple wordlines are activated simultaneously during the charging phase, the charges accumulated on ferroelectric field effect transistor cells within the same column may be transferred collectively to the same operational amplifier during the transfer phase. The operational amplifier may integrate the total charge received from all activated cells within the column, generating an output voltage that represents the weighted sum of the input voltages applied to the wordlines. The output voltage of the operational amplifiers may be proportional to the dot-product computational result of the wordline input voltage vector and the capacitive weight matrix pattern stored within the memory array 400.

The vector-matrix multiplication operations enabled by the two-phase reading process may provide parallel computational capabilities that accelerate mathematical operations for applications such as neural network inference and signal processing algorithms. The memory array 400 may be configured to perform these operations using charge-domain computing principles, where the mathematical operations are performed through physical charge redistribution processes rather than conventional digital arithmetic circuits. The charge-domain approach may offer advantages in power efficiency and computational speed compared to traditional digital processing methods, particularly for applications involving large matrix operations. The parallel nature of the charge accumulation and transfer processes may enable simultaneous computation of multiple output values, providing high throughput for computational tasks that require processing of large data sets.

The integration of individual ferroelectric field effect transistors into capacitive crossbar arrays may enable sophisticated vector-matrix multiplication operations that form the computational foundation for in-memory computing architectures. The system integration approach may leverage the charge-domain computational principles where mathematical operations are performed through controlled charge accumulation, redistribution, and sensing processes rather than conventional digital arithmetic circuits. The ferroelectric field effect transistors within the crossbar array may function as both storage elements and computational primitives, storing weight values through ferroelectric polarization states while simultaneously participating in multiplication and accumulation operations through capacitive coupling mechanisms. The parallel nature of the crossbar architecture may enable simultaneous processing of multiple input-output relationships, providing computational throughput that scales with the array dimensions and the number of simultaneously activated wordlines and bitlines.

The vector-matrix multiplication process may begin with the application of input voltage vectors to the wordlines of the capacitive crossbar array, where each voltage level represents a numerical input value for the computational operation. The ferroelectric field effect transistors connected to each wordline may respond to the applied voltages by accumulating charges proportional to both the input voltage magnitude and the stored capacitance values within each device. The charge accumulation process may occur simultaneously across all ferroelectric field effect transistors connected to the activated wordlines, enabling parallel multiplication operations where each device performs an individual multiplication between the input voltage and the stored weight value. The distributed nature of this multiplication process may eliminate the need for dedicated multiplier circuits and may reduce the computational latency associated with sequential arithmetic operations in conventional digital processors.

The accumulation phase of the vector-matrix multiplication may occur through the bitline connections that link ferroelectric field effect transistors within each column of the crossbar array. When multiple ferroelectric field effect transistors within the same column are activated simultaneously, the charges accumulated on each device may be combined through the common bitline connection during the charge transfer phase. The summation process may occur naturally through charge conservation principles, where the total charge transferred to each operational amplifier represents the sum of the individual charge contributions from all activated ferroelectric field effect transistors within the corresponding column. The operational amplifiers may convert the accumulated charge quantities into voltage signals that represent the dot-product results between the input vector and the weight matrix column stored within the crossbar array.

The capacitive approach to in-memory computing may provide substantial advantages over traditional resistive crossbar methods through the elimination of static power consumption during computational operations. Resistive crossbar arrays may require continuous current flow through the resistive elements during the application of input voltages, resulting in static power dissipation that scales with the magnitude of the applied voltages and the conductance values of the resistive elements. The capacitive approach may consume power only during the transient periods when charges are being accumulated or transferred, eliminating the steady-state power consumption that characterizes resistive implementations. The dynamic power consumption of capacitive systems may be proportional to the switching frequency and the capacitance values, allowing power optimization through careful control of operational timing and voltage levels.

The energy efficiency advantages of the capacitive approach may be particularly pronounced in applications involving large matrix operations or extended computational periods. The elimination of static power consumption may result in power savings of 10 to 100 times compared to resistive crossbar implementations, depending on the specific operational parameters and array dimensions. The power efficiency gains may enable deployment of in-memory computing systems in power-constrained environments such as mobile devices, edge computing platforms, and battery-powered sensor networks. The reduced power consumption may also decrease thermal management requirements and may enable higher integration densities without exceeding thermal design limits.

The capacitive crossbar architecture may provide enhanced signal integrity through the elimination of resistive voltage drops that can degrade computational accuracy in large resistive arrays. Resistive crossbar systems may experience significant voltage drops along the wordlines and bitlines due to the finite resistance of the interconnect structures and the current flow through multiple resistive elements. These voltage drops may cause the effective voltages applied to individual resistive elements to differ from the intended input values, introducing computational errors that accumulate across large arrays. The capacitive approach may avoid these issues through the open-circuit nature of capacitive elements, which may prevent steady-state current flow and the associated resistive voltage drops during computational operations.

The absence of sneak-path currents may represent another advantage of the capacitive crossbar approach compared to resistive implementations. Resistive crossbar arrays may experience unwanted current paths through non-selected resistive elements that can interfere with the intended computational operations and may degrade the accuracy of the results. These sneak-path currents may become more problematic as array sizes increase, potentially limiting the scalability of resistive crossbar systems. The capacitive approach may eliminate sneak-path issues through the inherent isolation provided by capacitive elements, which may block direct current flow while allowing controlled charge transfer during specific operational phases.

The compact cell area achievable with capacitive crossbar architectures may enable higher integration densities compared to resistive systems that require additional access transistors for each memory element. Many resistive crossbar implementations may utilize one-transistor-one-resistor configurations to provide individual cell selection and to prevent sneak-path currents, resulting in increased cell area and reduced array density. The capacitive approach may enable direct connection of ferroelectric field effect transistors between wordlines and bitlines without requiring separate access devices, reducing the cell area and increasing the number of computational elements that can be integrated within a given silicon area. The area efficiency gains may enable implementation of larger weight matrices and more complex computational operations within practical chip dimensions.

The read-disturbance-free operation of capacitive crossbar systems may provide enhanced reliability and data retention compared to resistive approaches that may experience gradual degradation during repeated read operations. Some resistive memory technologies may exhibit changes in resistance values when subjected to repeated read voltages, potentially causing drift in the stored weight values over extended operational periods. The capacitive read-out approach may utilize small-signal voltages that remain well below the coercive field threshold of the ferroelectric material, ensuring that read operations do not alter the stored polarization states or the associated capacitance values. The non-destructive nature of capacitive read operations may enable unlimited read cycles without degradation of the stored weight values, providing enhanced reliability for applications requiring frequent computational operations.

The system-level benefits of capacitive in-memory computing may extend beyond the individual advantages of power efficiency and signal integrity to encompass broader architectural improvements in computational systems. The elimination of data movement between separate processing and memory units may reduce the memory wall bottleneck that limits the performance of conventional computing architectures. The capacitive crossbar arrays may enable processing operations to occur directly within the memory array, reducing the latency and energy overhead associated with data transfer operations. The parallel processing capabilities may provide computational throughput that scales with the array dimensions, enabling acceleration of matrix-intensive algorithms such as neural network inference, signal processing, and scientific computing applications.

The scalability characteristics of capacitive crossbar systems may enable implementation of large-scale computational arrays that support complex algorithmic operations. The high capacitance on/off ratios achievable with ferroelectric field effect transistors may provide adequate signal margins for reliable operation of arrays containing hundreds of rows and columns, enabling storage and processing of weight matrices with tens of thousands of elements. The manufacturing compatibility with standard semiconductor fabrication processes may facilitate integration of capacitive crossbar arrays with conventional digital processing circuits, enabling hybrid computing architectures that combine the efficiency of analog in-memory computing with the flexibility of digital control and interface circuits. The system integration approach may enable deployment of capacitive in-memory computing in applications ranging from edge artificial intelligence accelerators to high-performance computing platforms for scientific and engineering applications.

A number of implementations have been described. Nevertheless, it will be understood that various modifications may be made without departing from the spirit and scope of the disclosure. Accordingly, other implementations are within the scope of the following claims.

1. A non-volatile capacitor device comprising:
a first metal layer;
a ferroelectric layer disposed on the first metal layer;
a semiconductor layer disposed on the ferroelectric layer; and
a second metal layer disposed on the semiconductor layer,
wherein the device has a tunable analog capacitance value that is programmable by voltage-driven pulses and maintains the capacitance value.

2. The device of claim 1, wherein the capacitance value is readable in a non-destructive manner by applying a voltage of less than 100 mV.

3. The device of claim 1, wherein the ferroelectric layer comprises doped HfO₂ based ferroelectric material.

4. The device of claim 1, wherein the semiconductor layer comprises silicon substrate.

5. The device of claim 1, wherein the semiconductor layer comprises polysilicon.

6. The device of claim 1, wherein the semiconductor layer comprises amorphous oxide semiconductor.

7. The device of claim 6, wherein the amorphous oxide semiconductor comprises indium oxide with dopants.

8. The device of claim 1, wherein the device is configured for front-end-of-line integration.

9. The device of claim 1, wherein the device is configured for back-end-of-line integration.

10. A capacitive array comprising:
a plurality of non-volatile capacitor devices arranged in rows and columns;
a plurality of word lines coupled to the rows;
a plurality of bit lines coupled to the columns; and
at least one operational amplifier coupled to the bit lines.

11. The capacitive array of claim 10, wherein the array is configured to perform vector-matrix multiplication operations.

12. The capacitive array of claim 10, wherein the array is configured for charge domain in-memory computing.

13. A method of operating a non-volatile capacitor device, the method comprising:
programming a capacitance value of the device by applying voltage-driven pulses to the device;
storing the capacitance value in the device without power supply; and
reading the capacitance value by applying a voltage of less than 100 mV to the device.

14. The method of claim 13, wherein the reading is performed in a non-destructive manner.

15. The method of claim 13, further comprising erasing the capacitance value by applying voltage-driven pulses of opposite polarity.

16. A neural network accelerator comprising:
a capacitive array; and
control circuitry configured to:
program capacitance values of the non-volatile capacitor devices to represent neural network weights,
apply input voltages representing neural network inputs to the word lines, and
read output signals from the bit lines representing neural network outputs.

17. The neural network accelerator of claim 16, wherein the control circuitry is further configured to perform vector-matrix multiplication operations using the capacitive array.

18. The neural network accelerator of claim 16, wherein the capacitive array performs charge domain in-memory computing operations.

19. A system for artificial intelligence acceleration comprising:
a plurality of non-volatile capacitor devices configured as synaptic weights; and
processing circuitry configured to perform neural network computations using the synaptic weights.

20. The system of claim 19, wherein the neural network computations comprise machine learning operations.
